(19) United States
(12) Patent Application Publication
(10) Pub. No.: US 2022/0416105 A1
(43) Pub. Date: Dec. 29, 2022

(54) PHOTOVOLTAIC TILE AND METHOD FOR MANUFACTURING THE SAME

(71) Applicant: FLEXTECH COMPANY, Wuhan (CN)

(72) Inventors: Jianghong GUI, Wuhan (CN); Yupeng GUI, Wuhan (CN)

(21) Appl. No.: 17/844,482

(22) Filed: Jun. 20, 2022

(30) Foreign Application Priority Data
Jun. 24, 2021 (CN) 202110703306.3

(51) Int. Cl. H01L 31/048

(52) U.S. Cl. CPC H01L 31/0481; H01L 31/049

(57) ABSTRACT

Provided are a photovoltaic tile and a method for manufacturing the photovoltaic tile. The photovoltaic tile includes a front film, a cell layer, an impact-resistant layer and a substrate, where an adhesive film is disposed between films of the photovoltaic tile, each of the front film and the adhesive film partially covers the substrate, the impact-resistant layer varies in dimension at a ratio being less than or equal to 0.5% before and after lamination, the substrate varies in dimension at a ratio being less than or equal to 0.5% before and after lamination, and the cell layer varies in dimension at a ratio being less than or equal to 0.5% before and after lamination.

### CROSS-REFERENCE TO RELATED APPLICATION(S)

This application claims priority to Chinese Patent Application No. 202110703306.3 filed Jun. 24, 2021, the disclosure of which is incorporated herein by reference in its entirety.

### TECHNICAL FIELD

The present disclosure relates to the technical field of photovoltaic buildings and, in particular, to a photovoltaic tile and a method for manufacturing the photovoltaic tile.

### BACKGROUND

Photovoltaic technology includes at least one of the most promising clean energy technologies because it can utilize an unlimited amount of solar energy and does not produce, like nuclear energy, harmful by-products that are difficult to process, nor does it produce, like burning fossil fuels and coals, a large amount of dust and greenhouse gases. In recent years, applications of the photovoltaic technology in the form of building-integrated photovoltaics (BIPV) have become increasingly popular. The BIPV may provide a full or partial power supply to electrical appliances at home or in a remote or mobile location, and various types of commercial and public facility.

One of the most common applications of the BIPV is to make a photovoltaic assembly into a roofing building component. This roofing building component has characteristics of waterproof, heat-insulating and capable of generating power. Compared with conventional building-applied photovoltaics (BAPV), the BIPV have the advantages of reducing roofing support structure and mounting costs, and making a building more aesthetic. Thus, the BIPV have a greater development potential.

A photovoltaic tile in which a fluoropolymer thin film is used as a surface and a metal or a non-metal backplane is used as a support has a relatively good application prospect. Such photovoltaic tiles are mostly manufactured through manners of thermal excitation, lamination and curing, and the photovoltaic tiles have the advantages of a light weight, a low cost and wide applicability. However, the production process has the following problems: (1) due to thermal expansion and cold contraction, different material layers have different variations in dimension, resulting in micro-cracks and breakage of cells during lamination; (2) the strong hydrophobicity and oleophobicity of the fluoropolymer thin film results in poor sealing performance at a position where adjacent photovoltaic tiles are spliced; (3) an existing structure of the photovoltaic tile cannot achieve reliable edge sealing, and it is difficult to replace a certain photovoltaic tile separately.

### SUMMARY

In view of above, a material and a process for manufacturing a photovoltaic tile are improved in the present disclosure, so that not only the effect of thermal expansion and cold contraction on the fragmentation of a cell piece is effectively reduced but also the manufactured photovoltaic tile is easy to assemble and replace and has better waterproof and sealing performance.

To achieve the above object, the technical solutions of the present disclosure are specifically described below.

An easy-to-mount photovoltaic tile, which is manufactured by a lamination method, includes a front film, a cell layer, an impact-resistant layer and a substrate, where an adhesive film is disposed between films of the photovoltaic tile, each of the front film and the adhesive film partially covers the substrate, the impact-resistant layer varies in dimension at a ratio being less than or equal to 0.5% before and after lamination, the substrate varies in dimension at a ratio being less than or equal to 0.5% before and after lamination, and the cell layer varies in dimension at a ratio being less than or equal to 0.5% before and after lamination. A ratio at which a dimension varies is a ratio of a variation (absolute value) between radial dimensions of a material layer before and after lamination to a radial dimension of the material layer before lamination.

Specifically, a material of the front film includes at least one of: ethylene-tetrafluoroethylene (ETFE), polyvinylidene fluoride (PVDF), ethylene-tetrafluoroethylene (EFTE), polyvinylfluoride (PVF), fluorinated ethylene propylene (FEP) and perfluoroalkoxy alkanes (PFA). When in use, a lower surface of a polymer film is pretreated by corona, plasma or the like. A material of the adhesive film is one or more of ethylene-vinyl acetate (EVA), polyethylene octene elastomer (POE), ethylene-methyl acrylate (EMA), ethylene-ethyl acrylate (EEA), a butyraldehyde resin, a polyurethane resin and silicone.

As a preferred technical solution, the impact-resistant layer includes a front impact-resistant layer disposed between the front film and the cell layer, and a back impact-resistant layer disposed between the cell layer and the substrate. It is to be understood that the front impact-resistant layer and the back impact-resistant layer may be made of the same material or different materials as long as the ratio at which the dimension varies is within an allowable range.

As a preferred technical solution, the substrate includes an aluminum alloy plate, and a material of the impact-resistant layer includes polyethylene terephthalate (PET) doped with a fiber.

More preferably, the fiber includes a glass fiber, a mass ratio of the glass fiber to polyethylene terephthalate is (18-22):100, and the glass fiber has a length ranging from 0.5 millimeter (mm) to 6 mm and a diameter being less than or equal to 20 micrometer (μm). Alternatively, the fiber is a carbon nanotube, a mass ratio of the carbon nanotube to polyethylene terephthalate is (0.1-1):100, and the carbon nanotube has a diameter ranging from 10 nanometer (nm) to 30 nm and a length ranging from 0.5 to 50 μm.

As a preferred technical solution, the substrate includes a support portion and a connection portion. The cell layer is disposed above the support portion and has a smaller dimension than the support portion, the back impact-resistant layer has a larger dimension than the cell layer and a smaller dimension than the support portion, and each of the front film and the adhesive film has a larger dimension than the support portion and partially covers the connection portion.

More preferably, the connection portion has an L-shaped section, the front film partially covers a vertical surface of the connection portion, and multiple mounting holes are disposed on a horizontal surface of the connection portion.

In a second aspect, the present disclosure provides a method for manufacturing the preceding easy-to-mount photovoltaic tile. The method includes a process described below.

In S1, an anti-adhesive layer having a preset width is coated on a periphery of the substrate, layers of materials are paved in sequence, evacuating, laminating, curing and annealing are performed to obtain a photovoltaic tile laminate.

In S2, the photovoltaic tile laminate is cut along an inner side of the anti-adhesive layer by using a laser cutter, and the anti-adhesive layer is removed together with a front film and an adhesive film on the anti-adhesive layer.

In S3, the photovoltaic tile laminate is bent by using a bending machine, wherein a bending region of each of the front film and the substrate has a radius of curvature R being greater than or equal to 3 mm.

In S4, a junction box is mounted and encapsulated with a glue.

As a preferred technical solution, the substrate needs to be pretreated. Specifically, the substrate is washed with an alkali, an acid and water in sequence, dried, and then cut and punched as required.

As a preferred technical solution, an evacuation process is specifically described below.

Paved members of the photovoltaic tile are conveyed through a conveyor belt to an evacuation chamber of a laminating machine.

A heating stage is warmed to 45-105° C., and the temperature of the heating stage is maintained.

An upper vacuum chamber is evacuated to a pressure of 0.05-0.08 Megapascal (MPa).

An upper cover is lowered.

A lower vacuum chamber is evacuated to a pressure of 0.02-0.05 MPa.

The lower vacuum chamber is inflated to normal pressure.

The upper cover is lifted.

As a preferred technical solution, a lamination and curing process is specifically described below.

The evacuated paved member of the photovoltaic tile is conveyed to a plane surface of a laminating vacuum chamber of a laminating machine.

An upper vacuum chamber is evacuated to a pressure of 0.05-0.08 MPa.

An upper cover is lowered.

A lower vacuum chamber is evacuated to a pressure of 0.02-0.05 MPa.

The heating stage is warmed to 60-100° C., and the temperature of heating stage is maintained.

The upper vacuum chamber is inflated to 0.03 MPa.

The heating stage is warmed to 100-120° C. and the temperature of heating stage is maintained.

The upper vacuum chamber is inflated to 0.05 MPa.

The heating stage is warmed to 120-160° C. and the temperature of heating stage is maintained.

The upper vacuum chamber is inflated to 0.08 MPa.

The upper vacuum chamber is evacuated for 1000-2400 s.

The lower vacuum chamber is inflated to normal pressure.

The upper cover is lifted.

As a preferred technical solution, an annealing process is specifically described below.

The laminated and cured paved members of the photovoltaic tile are conveyed to a plane surface of an annealing vacuum chamber of a laminating machine.

An upper vacuum chamber is evacuated to a pressure of 0.03-0.05 MPa.

An upper cover is lowered.

The upper vacuum chamber is inflated to a pressure of 0.06-0.08 MPa and the temperature of heating stage is maintained.

The heating stage is warmed to 115-160° C. and the temperature of heating stage is maintained.

A lower vacuum chamber is evacuated to a pressure of 0.03-0.05 MPa.

The upper vacuum chamber is inflated to normal pressure.

The upper cover is lifted.

The photovoltaic tile laminate is conveyed through a conveyor belt of the laminating machine to a discharge station.

As a preferred technical solution, operating parameters of the laser cutter in step S2 include that a conveyor belt has an operating speed of 0.1-0.3 meter per second (m/s) and a laser head has a power of 50-90 watt (W).

As a preferred technical solution, the junction box includes a positive junction box and a negative junction box configured on a front surface of the substrate.

The present disclosure has beneficial effects described below.

(1) In the present disclosure, a material of the impact-resistant layer is modified and thus has a reduced thermal shrinkage rate, effectively avoiding the bending and wrinkling of the photovoltaic tile laminate caused by different dimension variations of layers and significantly reducing a damage rate of the cell piece during lamination.

(2) The front film and the adhesive film partially cover the substrate. After an edge of the substrate is bent, a portion of the substrate uncovered with the front film may be overlapped, fixed and sealed with a sealant.

(3) Since the front film and the adhesive film have relatively good ductility during lamination, it is necessary to cut the front film and the adhesive film in order to control boundaries thereof. However, the front film and the adhesive film have good adhesion to the substrate after lamination so that it is difficult to completely remove the front film and the adhesive film after laser cutting. In the present disclosure, the anti-adhesive layer is coated on the substrate in advance. A material of the anti-adhesive layer does not affect the lamination and can assist in removing an excess front film and adhesive film after laser cutting.

### BRIEF DESCRIPTION OF DRAWINGS

FIG. 1 is a top view of a photovoltaic tile in example one.

FIG. 2 is a sectional view of a plane A-A in FIG. 1.

### DETAILED DESCRIPTION

The present disclosure is further described in detail in conjunction with drawings and examples, from which the object, technical solutions and advantages of the present disclosure are more apparent. It is to be understood that the embodiments described herein are merely intended to explain the present disclosure and not to limit the present disclosure.

### Example One

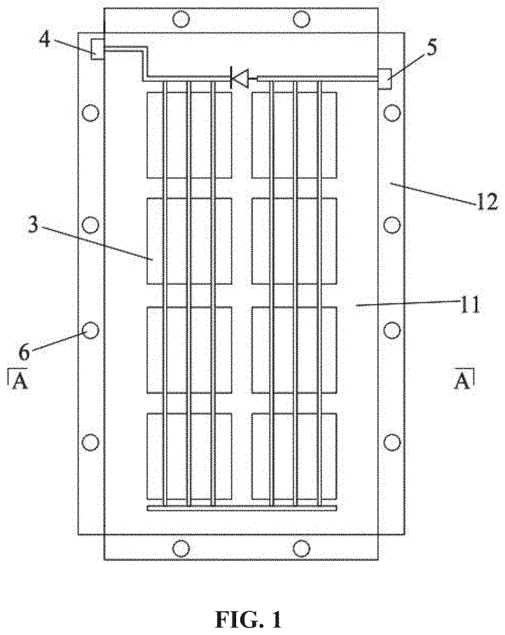

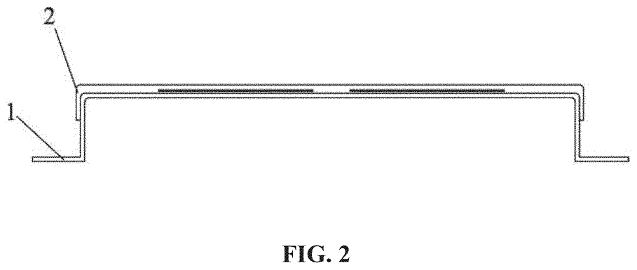

As shown in FIGS. 1 and 2, from bottom to top, an easy-to-mount photovoltaic tile includes: a substrate 1, a first adhesive film, a back impact-resistant layer, a second adhesive film, a cell layer 3, a third adhesive film, a front impact-resistant layer, a fourth adhesive film and a front film in sequence.

The substrate includes a support portion 11 and a connection portion 12 which is disposed on a periphery of the support portion 11. The support portion 11 has a square shape, the connection portion 12 has an L-shaped section, and several mounting holes 6 are disposed on a horizontal surface of the connection portion 12. It is to be understood that the support portion 11 and the connection portion 12 may be in different shapes according to actual needs. Each of the horizontal surface and a vertical surface of the connection portion 12 may be a plane surface, a curved surface or a concave-convex surface as long as connection portions of adjacent photovoltaic tiles can fit with each other in shape.

Each of the front impact-resistant layer and the back impact-resistant layer has a length and a width larger than those of the cell layer 3 and smaller than those of the support portion 11. The front impact-resistant layer and the back impact-resistant layer are made of the same material, which is PET doped with a glass fiber. A mass ratio of PET to the glass fiber is 100:20, and the glass fiber has a diameter being less than or equal to 20 micrometer (μm) and a length ranging from 0.5 millimeter (mm) to 3 mm.

The cell layer 3 consists of multiple solar cell pieces which are electrically connected to each other. The cell layer 3 has a smaller dimension than the front impact-resistant layer and the back impact-resistant layer.

The front film 2 has a larger dimension than the support portion 11 and extends to the connection portion 12. The front film 2 partially covers the connection portion 12. In the present example, the front film 2 partially covers the vertical surface of the connection portion 12.

In the present example, the substrate is made of an aluminum-magnesium-manganese alloy (specific components includes: 94.6-99.2% Al, 0.8-1.3% Mg, 0-1.6% Mn, 0-1.5% Cu and 0-1.0% Zn by weight), the front film is made of ETFE, and a material of the adhesive film is EVA.

A process of manufacturing the preceding easy-to-mount photovoltaic tile is described below.

(1) The substrate is pretreated, an anti-adhesive layer (polyurethane) having a width ranging from 10 mm to 15 mm is brushed and coated along a periphery of the substrate, and the mounting holes are perforated.

(2) The first adhesive film, the back impact-resistant layer, the second adhesive film, the cell layer, the third adhesive film, the front impact-resistant layer, the fourth adhesive film and the front film are paved on the substrate in sequence to obtain paved members of the photovoltaic tile.

(3) Electroluminescence (EL) testing is performed on the paved members of the photovoltaic tile, so as to filter out paved members of the photovoltaic tile which have a hidden crack, debris, a fragment, a black center, a black edge, pseudo soldering, a broken grid and other problems during the operation.

(4) The paved member of the photovoltaic tile is conveyed through a conveyor belt of a laminating machine to the laminating machine for lamination. A specific process is described below.

\textcircled{1} Evacuation and Dehumidification

The paved members of the photovoltaic tile are conveyed through the conveyor belt to an evacuation chamber of the laminating machine.

A heating stage is warmed to 45-105° C. and the temperature of heating stage is maintained.

An upper vacuum chamber is evacuated for 2-6 s to a pressure of 0.05-0.08 MPa.

An upper cover is lowered for 10 s.

A lower vacuum chamber is evacuated for 1000-3000 s to a pressure of 0.02-0.05 MPa.

The lower vacuum chamber is inflated to normal pressure and the pressure of lower vacuum chamber is maintained for 2-5 s.

The upper cover is lifted for 10 s.

\textcircled{2} Lamination and Curing

The evacuated paved members of the photovoltaic tile are conveyed to a plane surface of a laminating vacuum chamber of the laminating machine.

An upper vacuum chamber is evacuated for 2-8 s to a pressure of 0.05-0.08 MPa.

An upper cover is lowered for 10 s.

A lower vacuum chamber is evacuated for 60-360 s to a pressure of 0.02-0.05 MPa.

The heating stage is warmed to 60-100° C. and the temperature of heating stage is maintained for 360 s.

The upper vacuum chamber is inflated to 0.03 MPa.

The heating stage is warmed to 100-120° C. and the temperature of heating stage is maintained.

The upper vacuum chamber is inflated to 0.05 MPa and the pressure of upper vacuum chamber is maintained for 300 s.

The heating stage is warmed to 120-160° C. and the temperature of heating stage is maintained.

The upper vacuum chamber is inflated to 0.08 MPa.

The upper vacuum chamber is evacuated for 1000-2400 s.

The lower vacuum chamber is inflated to normal pressure and the pressure of lower vacuum chamber is maintained for 2-5 s.

The upper cover is lifted for 10 s.

\textcircled{3}Annealing

The laminated and cured paved members of the photovoltaic tile are conveyed to a plane surface of an annealing vacuum chamber of the laminating machine.

An upper vacuum chamber is evacuated for 2-8 s to a pressure of 0.03-0.05 MPa.

An upper cover is lowered for 10 s.

The upper vacuum chamber is inflated for 3-20 s to a pressure of 0.06-0.08 MPa and the pressure of the upper vacuum chamber is maintained.

The heating stage is warmed to 115-160° C. and the temperature of heating stage is maintained.

A lower vacuum chamber is evacuated for 1000-3000 s to a pressure of 0.03-0.05 MPa.

The upper vacuum chamber is inflated to normal pressure and the pressure of the upper vacuum chamber is maintained for 2-5 s.

The upper cover is lifted for 10 s.

The photovoltaic tile laminate is conveyed through the conveyor belt of the laminating machine to a discharge station.

(5) An edge of the photovoltaic tile laminate is trimmed by using a laser cutter. A specific process is described below.

The photovoltaic tile laminate is conveyed through a conveyor belt to a charge station of the laser cutter, and a position of the photovoltaic tile laminate is adjusted according to a predetermined region of a conveyor belt of the charge station. When a conveyor belt of a working platform of the laser cutter operates at a speed of 0.1-0.3 m/s, laser heads on two sides (the power of and the temperature of heating stage is maintained within an interval of 50-90 W) simultaneously cut the excess front film and adhesive film along an edge of an inner side of a non-adhesive tape. Then the photovoltaic tile laminate is conveyed to another laser cutter to cut the excess front film and adhesive film on the other two sides so that each of the above films has four sides which are 10-15 mm smaller than those of the substrate.

(6) The trimmed photovoltaic tile laminate is conveyed through a conveyor belt to a charge station of a crimping machine. After alignment, a lowering depth of the crimping machine is adjusted so that a bending region has a radius of curvature R being greater than or equal to 3 mm, ensuring the peel strength between the films in the bending region and the substrate has a loss being less than or equal to 10%.

(7) The bended photovoltaic tile is subjected to pressure resistance and insulating performance testing, EL testing and electrical performance testing.

(8) A junction box is mounted to the photovoltaic tile that has passed the testing. Specifically, the junction box includes a positive junction box and a negative junction box, where the positive junction box and the negative junction box are disposed on two opposing connection portions on a front surface of the substrate, respectively. Finally, the finished product is inspected, packaged and stored.

### Example Two

A difference from example one is described below.

Each of the front impact-resistant layer and the back impact-resistant layer is made of PET doped with a glass fiber, where a mass ratio of PET to the glass fiber is 100:18, and the glass fiber has a diameter being less than or equal to 20 μm and a length ranging from 0.5 mm to 6 mm.

### Example Three

A difference from example one is described below.

Each of the front impact-resistant layer and the back impact-resistant layer is made of PET doped with a carbon nanotube, where a mass ratio of PET to the carbon nanotube is 100:0.5, and the carbon nanotube has a diameter ranging from 10 nm to 30 nm and a length ranging from 0.5 μm to 50 μm.

### Example Four

A difference from example one is described below.

Each of the front impact-resistant layer and the back impact-resistant layer is made of PET doped with a carbon nanotube, where a mass ratio of PET to the carbon nanotube is 100:0.8, and the carbon nanotube has a diameter ranging from 10 nm to 30 nm and a length ranging from 0.5 μm to 50 μm.

### Comparative Example One

A difference from example one is described below.

Each of the front impact-resistant layer and the back impact-resistant layer is made of PET.

### Comparative Example Two

A difference from example one is described below.

The front impact-resistant layer and the back impact-resistant layer are made of the same material, which is PET doped with a glass fiber. A mass ratio of PET to the glass fiber is 100:27, and the glass fiber has a diameter ranging from 0.5 μm to 10 μm and a length ranging from 0.5 mm to 6 mm.

### Comparative Example Three

A difference from example one is described below.

Each of the front film and the adhesive film has the same dimension as the substrate, that is, the connection portion is completely covered with the front film and the adhesive film. It is to be noted that when the front film has the same dimension as the substrate, if both the positive junction box and the negative junction box are mounted on the front surface of the substrate, it is necessary to punch wire holes on the front film, thereby damaging the integrity of the front film and affecting the safety of a cell piece.

### CONCLUSION

(1) In examples one to four, each of the material of the impact-resistant layer, the material of the substrate and the cell piece varies in dimension at a ratio of less than 0.5% before and after lamination.

(2) As can be seen from the statistics and comparison of the EL testing data in step (7) in the examples, after lamination, each of the photovoltaic tiles in examples one to four has a significantly lower damage rate than that in comparative example one, indicating that the impact-resistant layer, which is made of a material modified by the carbon nanotube or the glass fiber, and the substrate experience similar thermal expansion and cold contraction in the lamination, curing and annealing process, thereby effectively eliminating the bending and wrinkling of the photovoltaic tile laminate and avoiding damages to the cell piece. However, the result of comparative example two shows that when too large an amount of glass fiber is doped, the damage rate increases compared with that of the photovoltaic tile with no glass fiber doped, which may be because the impact-resistant layer has too high a rigidity and thus loses certain flexibility. During the experiment, it is also found that when too small an amount of glass fiber is doped, the damage rate does not vary significantly; and when the content of the carbon nanotube is too high, the transmittance is affected to some extent.

(3) The photovoltaic tiles manufactured in example one are spliced and the photovoltaic tiles manufactured in comparative example three are spliced, separately. A specific process is described below.

Horizontal surfaces of connection portions of adjacent photovoltaic tiles are stacked, and mounting holes of the photovoltaic tiles are aligned. Bolts are screwed to a roofing batten after passing through the mounting holes of the above two photovoltaic tiles. In the same manner, the photovoltaic tiles are spliced one by one on four sides of each of the photovoltaic tiles. A positive junction box and a negative junction box of one photovoltaic tile are electrically connected to a negative junction box of one adjacent photovoltaic tile and a positive junction box of the other one adjacent photovoltaic tile, respectively. A waterproof material is poured into a slot at a joint of adjacent photovoltaic tiles. For the photovoltaic tile in example one, an upper surface of the waterproof material is lower than a lower edge of the front film. The waterproof material has good adhesion to the substrate in example one, achieving good waterproof and sealing effects. However, in comparative example three, the front film is bonded to the waterproof material with relatively poor performance due to hydrophobicity and oleophobicity, and thus a sealing material is extremely easy to fall off under an external force.

Finally, it is to be noted that the above are merely preferred examples of the present disclosure and not intended to limit the present disclosure. Although the present disclosure is described in detail with reference to the preceding examples, those skilled in the art can still modify the technical solutions described in the preceding examples or make equivalent substitutions on part of the technical features therein. Any modifications, equivalent substitutions, improvements and the like made within the spirit and principle of the present disclosure are within the scope of the present disclosure.

What is claimed is:

1. A photovoltaic tile, comprising a front film, a cell layer, an impact-resistant layer and a substrate, wherein an adhesive film is disposed between films of the photovoltaic tile, each of the front film and the adhesive film partially covers the substrate, the impact-resistant layer varies in dimension at a ratio being less than or equal to 0.5% before and after lamination, the substrate varies in dimension at a ratio being less than or equal to 0.5% before and after lamination, and the cell layer varies in dimension at a ratio being less than or equal to 0.5% before and after lamination.

2. The photovoltaic tile according to claim 1, wherein the impact-resistant layer comprises a front impact-resistant layer disposed between the front film and the cell layer, and a back impact-resistant layer disposed between the cell layer and the substrate.

3. The photovoltaic tile according to claim 1, wherein the substrate comprises an aluminum alloy plate, and a material of the impact-resistant layer comprises polyethylene terephthalate doped with a fiber.

4. The photovoltaic tile according to claim 3, wherein the fiber is a glass fiber, a mass ratio of the glass fiber to polyethylene terephthalate is (18-22):100, and the glass fiber has a length ranging from 0.5 millimeter (mm) to 6 mm and a diameter being less than or equal to 20 micrometer

5. The photovoltaic tile according to claim 3, wherein the fiber is a carbon nanotube, and a mass ratio of the carbon nanotube to polyethylene terephthalate is (0.1-1):100.

6. The photovoltaic tile according to claim 1, wherein the substrate comprises a support portion and a connection portion, wherein the cell layer is disposed above the support portion and has a smaller dimension than the support portion, a back impact-resistant layer has a larger dimension than the cell layer and a smaller dimension than the support portion, and each of the front film and the adhesive film has a larger dimension than the support portion and partially covers the connection portion.

7. The photovoltaic tile according to claim 6, wherein the connection portion has an L-shaped section, the front film partially covers a vertical surface of the connection portion, and a plurality of mounting holes are disposed on a horizontal surface of the connection portion.

8. A method for manufacturing the photovoltaic tile according to claim 1, comprising the following steps:
in S1, coating an anti-adhesive layer having a preset width on a periphery of the substrate, paving layers of materials in sequence, and performing evacuating, laminating, curing and annealing to obtain a photovoltaic tile laminate;
in S2, cutting the photovoltaic tile laminate along an inner side of the anti-adhesive layer by using a laser cutter, and removing the anti-adhesive layer together with a front film and an adhesive film on the anti-adhesive layer;
in S3, bending the photovoltaic tile laminate by using a bending machine, wherein a bending region of each of the front film and the substrate has a radius of curvature R being greater than or equal to 3 mm; and
in S4, mounting a junction box and encapsulating the junction box with a glue.

9. The method according to claim 8, wherein the junction box comprises a positive junction box and a negative junction box configured on a front surface of the substrate.

10. The method according to claim 8, wherein the anti-adhesive layer is made of a polyurethane material.
